(19) United States
(12) Patent Application Publication
(10) Pub. No.: US 2008/0195917 A1
(43) Pub. Date: Aug. 14, 2008

(54) METHOD AND APPARATUS FOR LOW COMPLEXITY SOFT OUTPUT DECODING FOR QUASI-STATIC MIMO CHANNELS

(75) Inventors: Chang-Soo Koo, Melville, NY (US); Nirav B. Shah, Syosset, NY (US); Robert Lind Olesen, Huntington, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 12/028,612

(22) Filed: Feb. 8, 2008

Related U.S. Application Data
(60) Provisional application No. 60/889,058, filed on Feb. 9, 2007.

(51) Int. Cl. H03M 13/00

(52) U.S. Cl. 714/780

(57) ABSTRACT

A method and apparatus for soft output decoding of multi-input multi-output (MIMO) channels in order to improve throughput performance is provided. In particular, a low-cost alternative to exhaustive brute-force maximum-likelihood search by using a variant of list decoding that exploits pre-coder linearity to reduce the computational complexity in generating a list of candidate codewords for decoding is disclosed.

### CROSS REFERENCE TO RELATED APPLICATION

This application claims the benefit of U.S. provisional application No. 60/889,058, filed on Feb. 9, 2007, which are incorporated by reference as if fully set forth.

### BACKGROUND

Wireless communications generally include communication stations which transmit and receive wireless communication signals between each other. Depending upon the type of system, communication stations typically are one of two types: base stations or wireless transmit/receive units (WTRUs), which include mobile units.

One type of wireless communication called a wireless local area network (WLAN), with one or more access points (APs) can be configured to conduct wireless communications with WTRUs equipped with WLAN modems. FIG. 1 illustrates an example of a WLAN including WTRUs designated 100, 102, 103, 104, along with an AP 106. The AP 106 has a coverage area 110. WTRUs generally include various components such as a transmitter 100_{T}, a receiver 100_{R}, a processor 100_{P} and a memory 100_{M} are illustrated for example in WTRU 100. WLANs can operate in infrastructure mode, where the WTRUs communicate with one or more access points, or in ad hoc mode, where non-base station WTRUs can communicate directly with each other in addition to communicating with the APs.

Some WTRUs are equipped with multiple antennas and are configured to process multi-input multi-output (MIMO) channel signals transmitted and received over such antennas.

Hereinafter, vectors are denoted by boldface lowercase characters, for example x, and matrices are denoted by boldface uppercase characters, for example H. Z, R, and C refer to the ring of integers, field of real numbers, and field of complex numbers, respectively.

In wireless communications, linearly pre-coded signals transmitted over an N×M flat-fading multi-input multi-output (MIMO) channel with additive white Gaussian noise (AWGN) are processed by a decoder at a receiver to estimate a transmitted signal. The class of linear pre-coders includes full diversity full rate threaded algebraic space time (TAST) pre-codes.

In general, a codeword of block length T at the output of the decoder is defined by a set of matrices C^{c}=[c₁^{c}, . . . , c_{T}^{c}] in C^{M×T}. The columns of the codeword C are transmitted in parallel on M transmit antennas in T channel uses. The received signal is designated by the sequence of vectors

$${y}_{t}^{c} = \sqrt{\frac{ρ}{M}} {H}^{c} {c}_{l}^{c} + {z}_{t}^{c} , t = 1 , … , T \qquad Equation ( 1 )$$

where the complex channel matrix H^{c} ε C^{N×M} is composed of independent and identically distributed (i.i.d) Gaussian elements h_{i,j}^{c}˜N_{c}(0,1), the noise has i.i.d. Gaussian components zᵢ^{c}˜N_{c}(0,1) and ρ denotes the signal-to-noise ratio (SNR) observed at a receive antenna.

Complex codewords are obtained by multiplexing every two components of a real codeword on one complex dimension. In the present context, a real codeword is defined by an m=2MT-dimension input quadrature amplitude modulation (QAM) vector and a generator matrix as follows:

c=Gx, for x ε U Equation (2)

where U ⊂ Z^{m} is the QAM alphabet and where the codeword is transmitted over T columns where every column has 2M real components.

The input-output relationship of the linearly pre-coded MIMO system can be expressed in the following vector form

y=HGx+z Equation (3)

where y ε Rⁿ denotes the received signal vector, z˜(0,1) is the AWGN vector, and H ε R^{n×m} is proportional through an appropriate scaling factor to the block-diagonal matrix

$${I}_{T} ⊗ [ \begin{matrix}Re \{ {H}^{c} \} & - Im \{ {H}^{c} \} \\ Im \{ {H}^{c} \} & Re \{ {H}^{c} \}\end{matrix} ] \qquad Equation ( 4 )$$

where \textcircled{x} denotes the Kronecker product, and where n=2NT and m=2MT.

The goal of soft output decoders is to compute a reliability value for each one of the input bits. The maximum a-posteriori (MAP) decoder computes the optimal log-likelihood ratios. In particular, let bᵢ be the i^{th} bits of the input vector x, then the log-likelihood ratio at the output of the MAP decoder is given by

$${L}_{i} = log ( \frac{{\sum }_{\{ x ( {b}_{i} = 1 ) \}} {e}^{- γ {‖ y - HGx ‖}^{2}}}{{\sum }_{\{ x ( {b}_{i} = 0 ) \}} {e}^{- γ {‖ y - HGx ‖}^{2}}} ) , \qquad Equation ( 5 )$$

where [x(b=0)] is the set of input vectors corresponding to bᵢ=0[x(b=1)] is defined similarly), and γ is a constant that depends on the signal-to-noise (SNR) ratio.

Here, the soft output decoder is the prohibitive computational complexity which grows exponentially with the size of x, where the exponential complexity is in the product of T and the transmission rate.

### SUMMARY

A method and apparatus for soft output decoding for a codebook-based multi-input multi-output (MIMO) channels includes a variant of list decoding which exploits the pre-coder linearity in minimizing the computational complexity needed to generate a set of codewords to derive the soft output symbols. The soft output decoding approximates the performance of the maximum a-posteriori (MAP) decoder while avoiding the excessive computational complexity of prior art decoders discussed above.

Generating a plurality of hard outputs based on the received linearly pre-coded signals to generate a second set of codeword that reduces the complexity to that of the hard-output decoder. The low complexity sequential decoder with simple soft output generation for soft-decision Turbo decoding using offline candidate lists of codewords associated with each codebook.

### BRIEF DESCRIPTION OF THE DRAWINGS

FIG. 1 is an illustration of a WLAN having WTRUs for wireless communication.

FIG. 2 is an illustration of a flow chart 200 of a method for soft output decoding for a codebook-based MIMO channels based on linearly pre-coded signals.

### DETAILED DESCRIPTION

When referred to hereafter the terminology base station includes, but is not limited to, a base station, Node B, site controller, access point or other interfacing device in a wireless environment that provides WTRUs with wireless access to a network with which the base station is associated.

When referred to hereafter the terminology WTRU includes, but is not limited to, a user equipment, mobile station, fixed or mobile subscriber unit, pager, or any other type of device capable of operating in a wireless environment. WTRUs include personal communication devices, such as phones, video phones, and Internet ready phones that have network connections. In addition, WTRUs include portable personal computing devices, such as PDAs and notebook computers with wireless modems that have similar network capabilities. WTRUs that are portable or can otherwise change location are referred to as mobile units. A base station is a type of WTRU.

A hard decision output is estimated using, for example, minimum mean square error (MMSE) estimation, the Lenstra Lenstra and Lovasz (LLL) algorithm with decision feedback equalization (LLL+DFE), or conventional soft decoding. Soft outputs are generated by selecting an offline candidate list associated with a codebook and shifting the candidate lattice points from the origin to the estimated hard decision output instead of centering them on the received point. Each candidate list is preferably obtained at the origin (or more specifically at a lattice point near the origin) for each codebook realization by executing a list soft decoder (SD) offline. Hence, the preferred candidate list does not depend on the received data points, and is executed only once for every codebook realization offline. In slow quasi-static fading channels, the decoding complexity reduces to that of the hard-output decoder.

The observation for soft-output list decoders is that the sum in the numerator (and similarly the sum of the denominator) is dominated by a few terms. The main idea in list decoding is, therefore, to approximate each sum by the few largest terms. More specifically, the list decoder identifies a candidate list of codewords C₁, and computes the i^{th} log-likelihood ratio as

$${L}_{i} \approx log ( \frac{{\sum }_{\{ x ( {b}_{i} = 1 ) ∈ {C}_{l} \}} {e}^{- γ {‖ y - HGx ‖}^{2}}}{{\sum }_{\{ x ( {b}_{i} = 0 ) ∈ {C}_{l} \}} {e}^{- γ {‖ y - HGx ‖}^{2}}} ) , \qquad Equation ( 6 )$$

where {x(bᵢ=1) ε Cₗ} is the set of input vectors in Cₗ with b=1. Assuming that Cₗ is identified by a the candidate list of codewords that approximate the log-likelihood ratio by the fewest terms in the numerator and denominator wherein the complexity of the decoder is only proportional to the list size instead of the set of all possible codewords.

A challenge in list decoding is to find Cₗ with a reasonable computational complexity. The disclosed method and apparatus uses linearity of the pre-coder and provides a sequential decoding framework to efficiently identify Cₗ.

First, a list is identified of size |Cₗ|−1 containing the codewords nearest to the origin for every channel realization (H). This process is implemented through a sphere decoder which finds all codewords within a sphere of radius rₗ around the origin, i.e., the sphere decoder finds the set of codewords x ε C′ₗ such that

∥HGx∥≦rₗ. Equation (7)

This process does not depend on the received codeword y, and hence, needs to be executed only once for every channel realization H. Accordingly, in relatively slow fading channels, the complexity of this step will only result in a marginal increase in the overall decoding complexity.

The second process corresponds to finding an approximate solution for the maximum likelihood decoding problem defined as

$${x}_{ML} = arg {min}_{x ∈ U} ‖ y - HG x ‖ . \qquad Equation ( 8 )$$

This can be implemented using any sequential decoding framework known in the art.

Finally, by using the linearity of the channel and pre-coder, a subset list of codewords is obtained by shifting every vector in C′ₗ to be centered around the maximum likelihood solution x_{ML} according to

Cₗ={x+x_{ML}|x ε C′ₗ}. Equation (9)

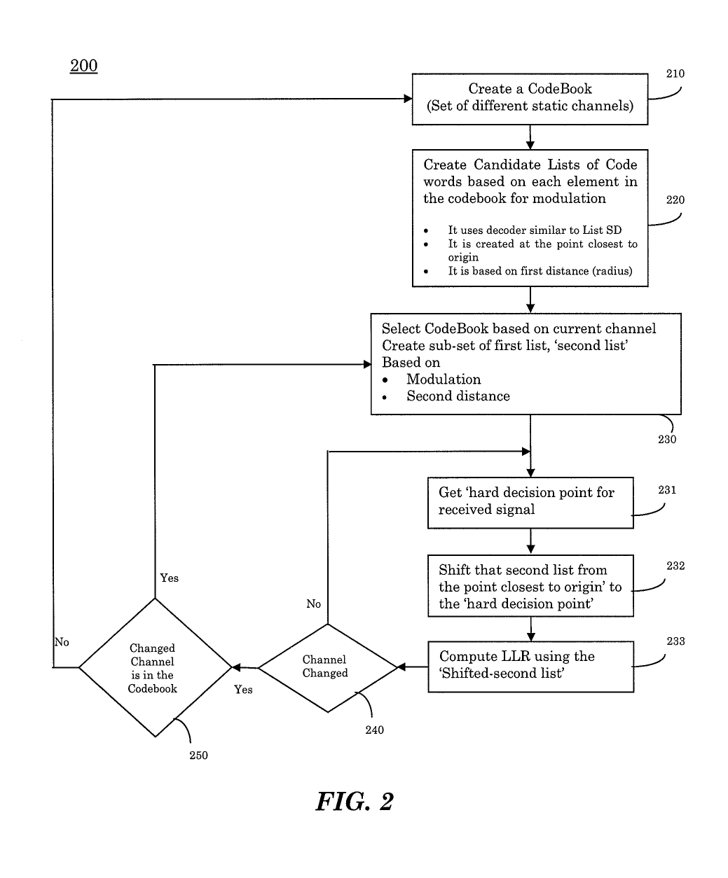

FIG. 2 is an illustration of a flow chart 200 of a method for soft output decoding for a codebook-based MIMO channels based on linearly pre-coded signals to generate a candidate list to derive the soft output symbols comprising the steps of 210 to 250. In step 210 a code book is created offline based on a set of different static channels. In step 220 a candidate list of codewords are created for each element in the codebook for different modulation. This candidate list in step 220 is created by using a list Sphere Decoder (SD), or similar decoder know to one skilled in the art, nearest to the origin for each element within a first distance around the origin. In step 230, a second list is generated which is subset of the candidate list in step 220 based on the modulation and a second distance where this second list is generated by steps 231 through 233. In step 231 a hard decision point is found for a received signal. Then, in step 232, the second list is shifted from the origin to the hard decision point, where in step 233 a log-likelihood ratio (LLR) is computed using the shifted second list. In step 240, if the channel does not change, then Steps 231 through 233 are repeated for each received signal. If the current channel is changed then go to step 250. In step 250, if the changed channel is included in the codebook then go to step 230 to select the codebook for the changed channel and repeat the steps 231 through 233 for each received signal for changed channel. If the changed channel is not in the codebook, then go to step 210 and create a new codebook.

Accordingly, the overall complexity needed for generating the list is reduced to that of approximating the maximum likelihood (ML) solution, as described above, which provide for much smaller complexities. The sequential decoding framework includes several implementations, for finding x_{ML}, that offer an excellent performance-complexity tradeoff. Also, the sphere radius, and hence the list size, can be varied as a function of the channel realization (H).

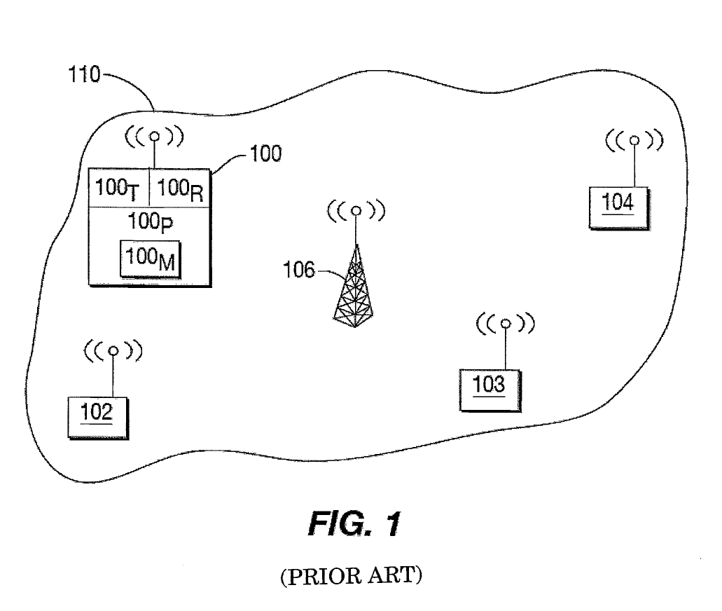

The present invention may be implemented in any type of wireless communication system, as desired. By way of example, the present invention may be implemented in any type of wireless communication system employing multi-input multi-output (MIMO) channels. The present invention may also be implemented on a digital signal processor (DSP), software or middleware. The present invention is preferably implemented as part of a wireless transmit/receive unit (WTRU) or a base station such as illustrated in FIG. 1.

Although the features and elements of the present invention are described in the preferred embodiments in particular combinations, each feature or element can be used alone without the other features and elements of the preferred embodiments or in various combinations with or without other features and elements of the present invention.

What is claimed is:

1. A method for decoding for multi-input multi-output (MIMO) signals in wireless communication, the method comprising:
receiving linearly pre-coded signals, having a modulation of constellation, transmitted over a Multiple-Input Multiple-Output (MIMO) channel;
selecting a candidate list containing a first set of codewords within a first specific distance to an origin for a channel realization to derive a soft output symbol;
generating a plurality of hard decision output from the received linearly pre-coded signals; and
shifting the candidate list from the origin to the hard decision output to generate a subset of the candidate list containing a second set of codewords within a second specific distance to the hard decision output to derive a subsequent soft output symbol.

2. The method of claim 1 wherein the candidate list is based in the linear pre-coding.

3. The method of claim 1 wherein the candidate list is generated offline.

4. The candidate list of claim 3 is associated with a cookbook.

5. The method of claim 1 wherein the first set of codewords from the candidate list is determined from the modulation of constellation.

6. The method of claim 1 wherein the hard decision output is determined by one of minimum mean square error (MMSE) estimation, Lenstra Lenstra and Lovasz (LLL) algorithm with decision feedback equalization (LLL+DFE), or maximum likelihood (ML) decoder.

7. The method of claim 6 wherein the ML decoder is implemented using sequential decoding framework.

8. The method of claim 1 wherein the linearly pre-coded signals include full diversity full rate Threaded Space-Time Architecture (TAST) pre-codes.

9. The method in claim 1 wherein the first set of codewords from the candidate list is implemented by a list sphere decoder nearest to the origin.

10. The method of claim 1 wherein the first set of codewords from the candidate list is executed once for every channel realization.

11. The method of claim 1 wherein the second set of codewords from the candidate list is generated by shifting the candidate list from the origin to the hard decision.

12. The method of claim 11 wherein a log-likelihood ratio for soft channel decoding is computed from the second set of codewords from the candidate list.

13. The method of claim 1 wherein the second set of codewords from the candidate is less than or equal to the first set of codewords from the candidate list of codewords.

14. The method of claim 11 wherein the log-likelihood ratio generates the soft output values used for the soft channel decoding.

15. The method of claim 1 wherein the hard decision output includes finding a nearby lattice point.

16. A Wireless Transmit/Receive Unit (WTRU) for receiving Multi-Input Multi-Output (MIMO) signals in wireless communication, the WTRU comprising:
a receiver for receiving linearly pre-coded signals, having a modulation of constellation, transmitted over a Multiple-Input Multiple-Output (MIMO) channel;
a first candidate list decoder for selecting a candidate list containing a first set of codewords within a first specific distance to an origin for a channel realization to derive a soft output symbol;
a hard decision decoder for generating a plurality of hard decision outputs from the received linearly pre-coded signals; and
a second candidate list decoder that shifts the candidate list from the origin to the hard decision output to generate a subset of the candidate list containing a second set of codewords within a second specific distance to the hard decision output to derive a subsequent soft output symbol.

17. The WTRU of claim 16 wherein the candidate list is based in the linear pre-coding.

18. The WTRU of claim 16 wherein the candidate list is generated offline.

19. The candidate list of claim 18 is associated with a cookbook.

20. The WTRU of claim 16 wherein the first set of codewords from the candidate list is determined from the modulation of constellation.

21. The WTRU of claim 16 wherein the hard decision output is determined by one of minimum mean square error (MMSE) estimation, Lenstra Lenstra and Lovasz (LLL) algorithm with decision feedback equalization (LLL+DFE), or maximum likelihood (ML) decoder.

22. The WTRU of claim 21 wherein the ML decoder is implemented using sequential decoding framework.

23. The WTRU of claim 16 wherein the linearly pre-coded signals include full diversity full rate Threaded Space-Time Architecture (TAST) pre-codes.

24. The WTRU in claim 16 wherein the first set of codewords from the candidate list is implemented by a list sphere decoder around the origin.

25. The WTRU of claim 16 wherein the first set of codewords from the candidate list is executed once for every channel realization.

26. The WTRU of claim 16 wherein the second set of codewords from the candidate list is generated by shifting the candidate list from the origin to the hard decision.

27. The WTRU of claim 26 wherein a log-likelihood ratio for soft channel decoding is computed from the second set of codewords from the candidate list.

28. The WTRU of claim 16 wherein the second set of codewords from the candidate is less than or equal to the first set of codewords from the candidate list of codewords.

29. The WTRU of claim 16 wherein the log-likelihood ratio generates the soft output values used for the soft channel decoding.

30. The WTRU of claim 16 wherein the hard decision output includes finding a nearby lattice point.
